(19) United States
(12) Patent Application Publication
(10) Pub. No.: US 2025/0138101 A1
(43) Pub. Date: May 1, 2025

(54) BATTERY PACK

(71) Applicant: Nuvoton Technology Corporation Japan, Kyoto (JP)

(72) Inventors: Susumu YOSHIKAWA, Shiga (JP); Hitoshi KOBAYASHI, Osaka (JP); Keiichi FUJII, Shiga (JP); Akira KAWABE, Osaka (JP)

(21) Appl. No.: 19/008,123

(22) Filed: Jan. 2, 2025

Related U.S. Application Data
(63) Continuation of application No. PCT/JP2023/020458, filed on Jun. 1, 2023.

(30) Foreign Application Priority Data
Jul. 13, 2022 (JP) 2022-112371

(51) Int. Cl. G01R 31/389; G01R 31/3842; H01M 50/129; H01M 50/548; H01M 50/55; H05K 9/00

(52) U.S. Cl. CPC G01R 31/389; G01R 31/3842; H01M 50/129; H01M 50/548; H01M 50/55; H05K 9/009

(57) ABSTRACT

A battery pack includes: an assembled battery in which power storage devices are connected; a current application line for applying current to the assembled battery; voltage detection lines for detecting voltages of the power storage devices; and a battery monitoring device that measures internal impedances of the power storage devices via the current application line and the voltage detection lines. Each of the power storage devices includes an electrode assembly in which a positive electrode plate and a negative electrode plate are alternately stacked, and an electrode plate on one principal surface of the electrode assembly and an electrode plate on the other principal surface of the electrode assembly have the same polarity, the direction of current that flows through the positive electrode plate is an opposite direction of the direction of current that flows through the negative electrode plate, and each of the power storage devices is stacked.

### CROSS REFERENCE TO RELATED APPLICATIONS

This is a continuation application of PCT International Application No. PCT/JP2023/020458 filed on Jun. 1, 2023, designating the United States of America, which is based on and claims priority of Japanese Patent Application No. 2022-112371 filed on Jul. 13, 2022. The entire disclosures of the above-identified applications, including the specifications, drawings and claims are incorporated herein by reference in their entirety.

### FIELD

The present invention relates to a battery pack including an assembled battery in which secondary batteries such as lithium-ion secondary batteries are connected in series or in parallel.

### BACKGROUND

In recent years, applications that use secondary batteries, such as environment-friendly vehicles including electric vehicles as well as storage batteries for stably supplying renewable energy have been increasing rapidly. In many cases, lithium-ion secondary batteries (also referred to as lithium-ion batteries (LiBs)) are used for such applications for their high energy density.

In many cases, an automotive battery or a storage battery includes an assembled battery in which secondary batteries are arranged aligned and connected in series or in parallel. Since an assembled battery allows using electricity for a long time, an increase in capacitance is demanded. For this reason, such an assembled battery is designed to have a structure in which a battery block including secondary batteries stacked in plural layers is accommodated in a metallic or plastic outer case. This assembled battery can increase an output voltage by connecting secondary batteries in series, and increase the use time of the assembled battery by connecting secondary batteries in parallel. It is known that the use of lithium-ion secondary batteries accelerates degradation caused by overcharge, overdischarge, or temperature, which may lead to a dangerous state such as smoking and firing, and even an explosion in the worst case. Therefore, a battery monitoring device is normally provided to place the lithium-ion batteries under appropriate control.

A battery monitoring device, in general, monitors voltages, currents, and temperatures of all of secondary batteries that constitute an assembled battery, and monitors the state of each secondary battery using measurement data obtained through the monitoring.

PTL 2 discloses a high-output and high-capacity battery pack that includes an assembled battery in which a plurality of secondary batteries are assembled.

In the battery pack disclosed in PTL 2, the assembled battery is formed by stacking secondary batteries, a circuit board on which a battery monitoring device is mounted is disposed on an end face of the assembled battery, and voltage detection lines connect the secondary batteries included in a battery block to the circuit board disposed on the end face of the assembled battery. Voltage detection lines are placed at a terminal face on which the electrode terminal of each secondary battery is located, and is also placed in the external space of the electrode terminal. The voltage detection lines connected to the electrode terminals are led out to the edge portion of the assembled battery on the circuit board side in the longitudinal direction of the assembled battery.

PTL 3 discloses techniques of measuring impedance of a secondary battery as one method for monitoring the state of the secondary battery. PTL 3 proposes a battery monitoring device capable of measuring internal impedance properties of a secondary battery using electrochemical impedance spectroscopy (EIS), and monitoring, in real time, the state of the secondary battery. This battery monitoring device enables also measuring impedance of a secondary battery, referencing the correlation between (i) predetermined impedance and (ii) state of charge (SOC) and state of health (SOH) of the secondary battery, estimating the SOC and SOH corresponding to the measured impedance, and managing the battery state.

However, since a response signal obtained by internal impedance properties is an extremely weak signal, a problem is that the signal is likely to receive an external influence. One example of such a problem is electromagnetic induction disturbance that induced electromotive force is generated in an electrical circuit path along which a response signal is input or output when internal impedance of a secondary battery is measured, and accurate measurement cannot be performed due to an influence caused by the induced electromotive force.

In view of this, PTL 4 proposes a battery monitoring device that defines the minimum range of an area surrounded by an electrical circuit path in which induced electromotive force is generated, and is thus capable of suppressing an influence caused by induced electromotive force.

### CITATION LIST

### Patent Literature

PTL 1: Japanese Unexamined Patent Application Publication No. 2017-68972

PTL 2: Japanese Unexamined Patent Application Publication No. 2015-185414

PTL 3: Japanese Patent No. 5403437

PTL 4: Japanese Unexamined Patent Application Publication No. 2021-117221

### SUMMARY

### Technical Problem

In a power storage device such as a secondary battery in which an electrode assembly is sealed, a magnetic field generated in the power storage device passes through and exits the battery. When a plurality of such power storage devices are connected to constitute an assembled battery, a problem is that a magnetic field generated in a power storage device interferes with other power storage devices and impedance, such as an electrode or an electrolyte, derived from a battery cannot be accurately measured.

In view of this, the present disclosure provides a battery pack capable of accurately measuring internal impedances of power storage devices included in an assembled battery.

### Solution to Problem

A battery pack according to the present disclosure includes: an assembled battery in which a plurality of power storage devices are connected; a current application line for applying current to the assembled battery; voltage detection lines for detecting voltages of the plurality of power storage devices; and a battery monitoring device that measures internal impedances of the plurality of power storage devices via the current application line and the voltage detection lines. Each of the plurality of power storage devices includes an electrode assembly in which a positive electrode plate and a negative electrode plate are alternately stacked, and an electrode plate on one principal surface of the electrode assembly and an electrode plate on the other principal surface of the electrode assembly have the same polarity. The direction of current that flows through the positive electrode plate is an opposite direction of the direction of current that flows through the negative electrode plate. Each of the plurality of power storage devices is stacked.

A battery pack according to the present disclosure includes: an assembled battery in which a plurality of power storage devices are connected; a current application line for applying current to the assembled battery; voltage detection lines for detecting voltages of the plurality of power storage devices; and a battery monitoring device that measures internal impedances of the plurality of power storage devices via the current application line and the voltage detection lines. Each of the plurality of power storage devices includes an electrode assembly in which a positive electrode plate and a negative electrode plate are alternately stacked, the positive electrode plate is placed on one principal surface of the electrode assembly, and the negative electrode plate is placed on the other principal surface of the electrode assembly. The direction of current that flows through the positive electrode plate is an opposite direction of the direction of current that flows through the negative electrode plate. Each of the plurality of power storage devices is stacked so that the positive electrode plate on the one principal surface of the electrode assembly in each of the plurality of power storage devices is adjacent to the positive electrode plate on the one principal surface of the electrode assembly in a neighboring power storage device, and the negative electrode plate on the other principal surface of the electrode assembly in each of the plurality of power storage devices is adjacent to the negative electrode plate on the other principal surface of the electrode assembly in a neighboring power storage device.

### Advantageous Effects

A battery pack according to one aspect of the present disclosure is capable of accurately measuring the internal impedances of power storage devices included in an assembled battery.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a schematic configuration diagram illustrating one example of a battery pack according to Embodiment 1.

FIG. 2A is a diagram for illustrating a Nyquist plot.

FIG. 2B is a diagram for illustrating a Nyquist plot.

FIG. 3 is a diagram for illustrating the correlation between a Nyquist plot and the equivalent circuit of a lithium-ion secondary battery.

FIG. 4 is a perspective view illustrating a secondary battery.

FIG. 5 is a configuration diagram illustrating an electrode assembly according to Embodiment 1.

FIG. 6 is a perspective view illustrating an arrangement of a plurality of secondary batteries according to Embodiment 1.

FIG. 7 is a diagram illustrating a method of connecting a current application line according to Embodiment 1.

FIG. 8 is a diagram for illustrating magnetic fluxes generated from a secondary battery according to Embodiment 1.

FIG. 9 is a diagram for illustrating magnetic fluxes generated from an electrode assembly according to Embodiment 1.

FIG. 10 is a diagram for illustrating interference of magnetic fluxes generated from neighboring secondary batteries according to Embodiment 1.

FIG. 11 is a diagram for illustrating magnetic fluxes generated from an assembled battery according to Embodiment 1.

FIG. 12 is a perspective view illustrating an arrangement of secondary batteries that causes electromagnetic induction disturbance.

FIG. 13 is a diagram illustrating an influence caused by electromagnetic induction disturbance.

FIG. 14 is a perspective view illustrating an arrangement of a plurality of secondary batteries according to Embodiment 2.

FIG. 15 is a perspective view illustrating an arrangement of a plurality of secondary batteries according to Embodiment 3.

FIG. 16 is a plan view illustrating one example of a secondary battery and a connector according to Embodiment 4.

FIG. 17 is a diagram illustrating wires that connect battery terminals and connectors according to Embodiment 4.

FIG. 18 is a diagram illustrating a method of connecting a current application line according to Embodiment 4.

FIG. 19 is a diagram illustrating a method of connecting voltage detection lines according to Embodiment 4.

FIG. 20 is a perspective view illustrating an arrangement example of electromagnetic shields according to Embodiment 5.

### DESCRIPTION OF EMBODIMENTS

A battery pack according to one aspect of the present disclosure includes: an assembled battery in which a plurality of power storage devices are connected; a current application line for applying current to the assembled battery; voltage detection lines for detecting voltages of the plurality of power storage devices; and a battery monitoring device that measures internal impedances of the plurality of power storage devices via the current application line and the voltage detection lines. Each of the plurality of power storage devices includes an electrode assembly in which a positive electrode plate and a negative electrode plate are alternately stacked, and an electrode plate on one principal surface of the electrode assembly and an electrode plate on the other principal surface of the electrode assembly have the same polarity. The direction of current that flows through the positive electrode plate is an opposite direction of the direction of current that flows through the negative electrode plate. Each of the plurality of power storage devices is stacked.

With this, an electrode plate on the outermost surface of each of the plurality of power storage devices and an electrode plate on the outermost surface of a power storage device adjacent in the stacking direction of the power storage devices have the same polarity, and it is thus possible to mutually weaken magnetic fluxes generated from the electrode plates having the same polarity on the outermost surfaces of neighboring power storage devices. Accordingly, a magnetic flux generated in a power storage device included in the assembled battery is less likely to interfere with other power storage devices, and it is thus possible to accurately measure the internal impedance of each power storage device.

For example, a positive electrode side battery terminal and a negative electrode side battery terminal of each of the plurality of power storage devices may protrude in the same direction. The positive electrode side battery terminals of the plurality of power storage devices may at least partially overlap each other when viewed from the stacking direction of the plurality of power storage devices. The negative electrode side battery terminals of the plurality of power storage devices may at least partially overlap each other when viewed from the stacking direction of the plurality of power storage devices. Alternatively, a positive electrode side battery terminal and a negative electrode side battery terminal of each of the plurality of power storage devices may protrude in opposite directions. The positive electrode side battery terminals of the plurality of power storage devices may at least partially overlap each other when viewed from the stacking direction of the plurality of power storage devices. The negative electrode side battery terminals of the plurality of power storage devices may at least partially overlap each other when viewed from the stacking direction of the plurality of power storage devices.

With this, it is possible to mutually weaken magnetic fluxes generated from the positive electrode side battery terminals of neighboring power storage devices, and mutually weaken also magnetic fluxes generated from the negative electrode side battery terminals of neighboring power storage devices. Accordingly, a magnetic flux generated in a power storage device included in the assembled battery is much less likely to interfere with other power storage devices, and it is thus possible to more accurately measure the internal impedance of each power storage device. When the positive electrode side battery terminal and the negative electrode side battery terminal of each of the power storage devices protrude in opposite directions, the distance between the positive electrode side battery terminal and the negative electrode side battery terminal can be increased, magnetic fluxes are less likely to interfere with each other between the battery terminals, and it is thus possible to more accurately measure the internal impedance of each power storage device.

A battery pack according to one aspect of the present disclosure includes: an assembled battery in which a plurality of power storage devices are connected; a current application line for applying current to the assembled battery; voltage detection lines for detecting voltages of the plurality of power storage devices; and a battery monitoring device that measures internal impedances of the plurality of power storage devices via the current application line and the voltage detection lines. Each of the plurality of power storage devices includes an electrode assembly in which a positive electrode plate and a negative electrode plate are alternately stacked, the positive electrode plate is placed on one principal surface of the electrode assembly, and the negative electrode plate is placed on the other principal surface of the electrode assembly. The direction of current that flows through the positive electrode plate is an opposite direction of the direction of current that flows through the negative electrode plate. Each of the plurality of power storage devices is stacked so that the positive electrode plate on the one principal surface of the electrode assembly in each of the plurality of power storage devices is adjacent to the positive electrode plate on the one principal surface of the electrode assembly in a neighboring power storage device, and the negative electrode plate on the other principal surface of the electrode assembly in each of the plurality of power storage devices is adjacent to the negative electrode plate on the other principal surface of the electrode assembly in a neighboring power storage device.

With this, an electrode plate on the outermost surface of each of the plurality of power storage devices and an electrode plate on the outermost surface of a power storage device adjacent in the stacking direction have the same polarity, and it is thus possible to mutually weaken magnetic fluxes generated from the electrode plates having the same polarity in neighboring power storage devices. Accordingly, a magnetic flux generated in a power storage device included in the assembled battery is less likely to interfere with other power storage devices, and it is thus possible to accurately measure the internal impedance of each power storage device.

For example, a positive electrode side battery terminal and a negative electrode side battery terminal of each of the plurality of power storage devices may protrude in the same direction. The positive electrode side battery terminals of the plurality of power storage devices may at least partially overlap each other when viewed from the stacking direction of the plurality of power storage devices. The negative electrode side battery terminals of the plurality of power storage devices may at least partially overlap each other when viewed from the stacking direction of the plurality of power storage devices.

Stacking each of the power storage devices so that the positive electrode side battery terminal and the negative electrode side battery terminal of each of the power storage devices overlap enables an electrode plate on the outermost surface of each of the power storage devices and an electrode plate on the outermost surface of a power storage device adjacent in the stacking direction of the power storage devices to have the same polarity.

For example, each of the plurality of power storage devices may have a structure in which the electrode assembly is sealed by a laminated sheet including a resin layer and a metal layer.

In a laminated power storage device for which a laminated sheet is used for the material of the housing of the laminated power storage device, a magnetic field generated in the laminated power storage device passes through and exits the laminated power storage device. When an assembled battery includes laminated power storage devices, a magnetic field generated in a laminated power storage device is likely to interfere with other laminated power storage devices, and it is difficult to accurately measure impedance, such as an electrode or an electrolyte, derived from a laminated power storage device. However, with the battery pack according to the present disclosure, even when the assembled battery includes laminated power storage devices, a magnetic flux generated in a laminated power storage device included in the assembled battery is less likely to interfere with other laminated power storage devices, and it is thus possible to accurately measure the internal impedance of each laminated power storage device.

For example, in the assembled battery, the current application line may be placed between a positive electrode side battery terminal and a negative electrode side battery terminal of each of the plurality of power storage devices.

With a current application line interposed between the positive electrode side battery terminal and the negative electrode side battery terminal of each of the plurality of power storage devices, it is possible to make the length of the current application line the shortest. It is therefore possible to suppress an influence caused by a magnetic flux generated from the current application line, thereby more accurately measuring the internal impedance of each power storage device included in the assembled battery.

For example, the battery pack may further include a connector that places battery terminals included in the plurality of power storage devices so as to overlap each other when viewed from the stacking direction of the plurality of power storage devices.

With such a connector placing battery terminals in the up-down direction as described above, the area of a current loop can be minimized and an influence caused by electromagnetic induction disturbance can be suppressed. With this, it is possible to more accurately measure the internal impedance of each power storage device included in the assembled battery.

For example, the battery pack may further include a shielding part that shields an electric field or a magnetic field generated by the plurality of power storage devices.

With such a shielding part as described above, it is possible to suppress an influence caused by an electric field or a magnetic field generated by a power storage device.

Hereinafter, embodiments of the present disclosure will be described with reference to the drawings. The embodiments described below each illustrate a general or specific example of the present disclosure. The numerical values, shapes, materials, elements, the arrangement and connection of the elements, etc., shown in the following embodiments are mere examples, and therefore do not limit the scope of the present disclosure. Among the elements in the following embodiments, those not recited in any of the independent claims are described as optional elements.

The figures are schematic diagrams and are not necessarily precise illustrations. Elements that are essentially the same share the same reference signs in the figures, and duplicate description is omitted or simplified.

### Embodiment 1

Battery pack 2 according to Embodiment 1 will be described.

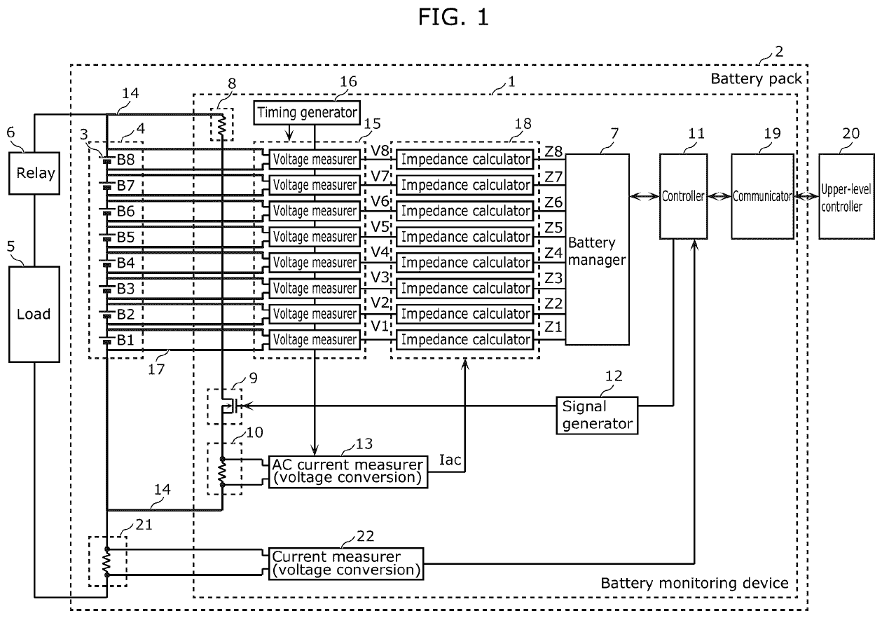

FIG. 1 is a schematic configuration diagram illustrating one example of battery pack 2 according to Embodiment 1. FIG. 1 illustrates, besides battery pack 2, higher-level controller 20, load 5, and relay 6.

Hereinafter, an example in which battery pack 2 is applied to the power supply system of a vehicle (e.g., a hybrid electric vehicle or an electric vehicle) will be described.

As illustrated in FIG. 1, battery pack 2 includes: assembled battery 4 in which a plurality of secondary batteries 3 (e.g., secondary batteries B1 to B8) are combined and connected; battery monitoring device 1 that monitors secondary batteries 3; current application line 14; voltage detection lines 17; and shunt resistor 21. Secondary batteries 3 are secondary batteries such as lithium-ion secondary batteries. Secondary battery 3 is one example of a power storage device.

Relay 6 that turns ON or OFF the connection between assembled battery 4 and load 5 (corresponding to a motor, an inverter, or an accelerator) is provided between assembled battery 4 and load 5. An application is operated in accordance with ON or OFF of the connection between assembled battery 4 and load 5 by relay 6. When the plurality of secondary batteries 3 are storage batteries, load 5 may be a charger. Assembled battery 4 and battery monitoring device 1 are connected by current application line 14 and voltage detection lines 17.

Battery monitoring device 1 measures internal impedances of the plurality of secondary batteries 3 via current application line 14 and voltage detection lines 17. For example, battery monitoring device 1 measures internal impedance (e.g., internal alternating-current (AC) impedance) of each of the plurality of secondary batteries 3. Battery monitoring device 1 measures internal AC impedances of the plurality of secondary batteries 3 (e.g., internal AC impedance of each of the plurality of secondary batteries 3) based on AC current applied to assembled battery 4 and voltages of the plurality of secondary batteries 3 included in assembled battery 4. For example, battery monitoring device 1 measures internal AC impedance properties of secondary battery 3 using EIS, and monitors, in real time, the state of secondary battery 3. Battery monitoring device 1 includes battery manager 7, load resistor 8, switching element 9, shunt resistor 10, controller 11, signal generator 12, AC current measurer 13, voltage measurer 15, timing generator 16, impedance calculator 18, communicator 19, shunt resistor 21, and current measurer 22.

Battery manager 7, controller 11, signal generator 12, AC current measurer 13, voltage measurer 15, timing generator 16, and impedance calculator 18 are functional components for measuring the internal AC impedance of assembled battery 4 (specifically, the plurality of secondary batteries 3 included in assembled battery 4).

Load resistor 8, switching element 9, and shunt resistor 10 are circuits for measuring the internal AC impedance of assembled battery 4.

With controller 11 controlling signal generator 12 that sweeps an AC signal, it is possible to turn switching element 9 ON or OFF at a specific frequency. With this, AC current at a specific frequency is output from assembled battery 4. AC current measurer 13 measures a voltage generated in shunt resistor 10 (i.e., a voltage obtained by converting the AC current output from assembled battery 4). Load resistor 8 and assembled battery 4 as well as shunt resistor 10 and assembled battery 4 are respectively connected via current application line 14. Since load resistor 8 and shunt resistor 10 are included in battery monitoring device 1, battery monitoring device 1 and assembled battery 4 are connected via current application line 14. Current application line 14 is a wire for applying AC current to assembled battery 4. Current application line 14 is, for example, a conductor.

Voltage measurer 15 measures voltages of the plurality of secondary batteries 3 included in assembled battery 4. Voltage measurer 15 may measure voltages of all of secondary batteries 3 included in assembled battery 4. Alternatively, voltage measurer 15 may measure voltages of some (at least two) of secondary batteries 3 included in assembled battery 4, i.e., assembled battery 4 may include secondary batteries 3 whose voltages are not to be measured by voltage measurer 15. Moreover, since voltage measurer 15 measures voltages of the plurality of secondary batteries 3 included in assembled battery 4, controller 11 sets measurement timing via timing generator 16.

Voltage measurer 15 is connected to the plurality of secondary batteries 3 via voltage detection lines 17, and measures voltages of the plurality of secondary batteries 3 (e.g., voltage of each of the plurality of secondary batteries 3). Voltage detection lines 17 are wires for detecting the voltages of the plurality of secondary batteries 3 (e.g., the voltage of each of the plurality of secondary batteries 3). For example, voltage detection line 17 is connected to the positive electrode side battery terminal and the negative electrode side battery terminal of each of the plurality of secondary batteries 3, as illustrated in FIG. 1. In the example illustrated in FIG. 1, sixteen voltage detection lines 17 are provided for eight secondary batteries B1 to B8. Voltage detection lines 17 are, for example, conductors.

Voltages V1 to V8 of secondary batteries B1 to B8 measured by voltage measurer 15 and current value Iac measured and converted into voltage by AC current measurer 13 are used for the calculation (voltage divided by current) of impedances Z1 to Z8 of secondary batteries B1 to B8 by impedance calculator 18. Impedances Z1 to Z8 are each a complex number, and real part ReZ and imaginary part ImZ are calculated for each of secondary batteries B1 to B8. Complex impedance values Z1 to Z8 of secondary batteries B1 to B8 are output from impedance calculator 18 to battery manager 7, and battery manager 7 determines the SOC and SOH of and an anomaly (breakdown or deterioration) in each of secondary batteries B1 to B8. The SOC, SOH of and an anomaly in each of secondary batteries B1 to B8 are then notified to higher-level controller 20 via controller 11 and communicator 19. Higher-level controller 20 performs control in accordance with the notified SOC, SOH, and anomaly.

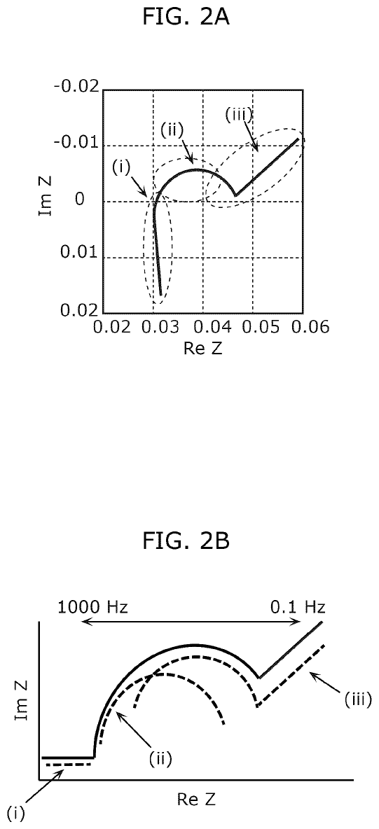

Impedance calculator 18 calculates the complex impedance of secondary battery 3 that is a ratio between voltage measured by voltage measurer 15 and current measured by AC current measurer 13 at each frequency when signal generator 12 outputs AC current from assembled battery 4 at each frequency. A Nyquist plot as illustrated in FIG. 2A or FIG. 2B can be obtained by plotting the calculated complex impedances on a complex plane.

FIG. 2A and FIG. 2B are each a diagram for illustrating a Nyquist plot. In FIG. 2A and FIG. 2B, the horizontal axis indicates real part ReZ of complex impedance Z and the vertical axis indicates imaginary part ImZ of complex impedance Z.

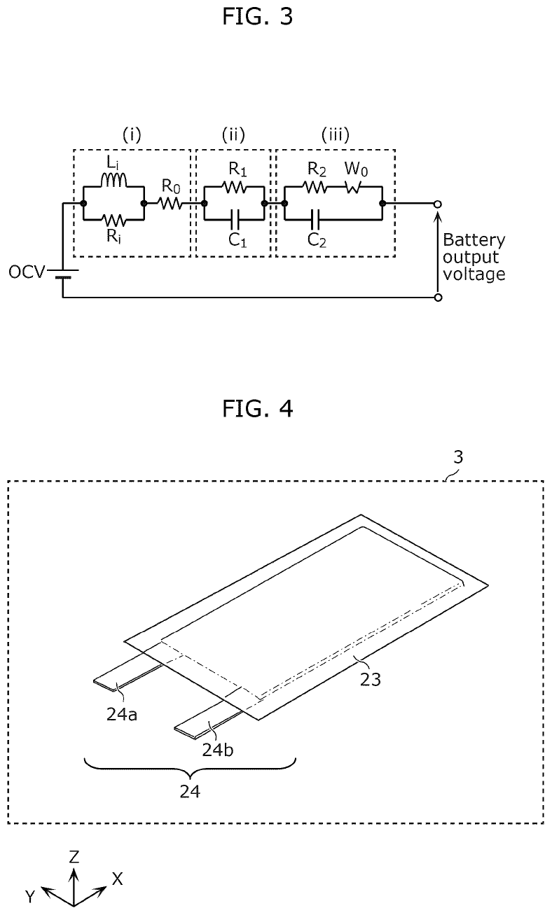

In the Nyquist plot as illustrated in FIG. 2A or FIG. 2B, a polyline is divided into sections (i) to (iii) and the impedance components of a lithium-ion secondary battery can be analyzed, for example. Area (i) corresponds to the impedance of transfer resistance in a wire or the electrolyte of the lithium-ion secondary battery. The semicircular parts of sections (ii) and (iii) correspond to the impedances of charge transfer resistance of the lithium-ion secondary battery, section (ii) corresponds to the impedance of a negative electrode, and section (iii) corresponds to the impedance of a positive electrode. An influence caused by Warburg impedance of a lithium-ion secondary battery is reflected in a straight portion that rises at approximately 45 degrees in the low-frequency range of a section defined by ImZ<0. For example, the equivalent circuit of a lithium-ion secondary battery as illustrated in FIG. 3 can be estimated from the Nyquist plot thus created.

FIG. 3 is a diagram for illustrating the correlation between a Nyquist plot and the equivalent circuit of a lithium-ion secondary battery.

FIG. 3 illustrates one example of the equivalent circuit of the internal resistance of a lithium-ion secondary battery. In the equivalent circuit illustrated in this example, resistance R0 corresponds to transfer resistance in an electrolyte, resistance R1 corresponds to the charge transfer resistance of a negative electrode, and resistance R2 corresponds to the charge transfer resistance of a positive electrode. Wiring is defined by a parallel circuit including inductor Li and resistance Ri. Warburg resistance WO indicates dispersion and is serial connected to resistance R2. A circuit in which resistance R0 is serial connected to a parallel circuit including inductor Li and resistance Ri corresponds to graph line (i) in the Nyquist plot illustrated in FIG. 2A or FIG. 2B. An RC parallel circuit including resistance R1 and capacitor C1 corresponds to graph line (ii) in the Nyquist plot illustrated in FIG. 2A or FIG. 2B. An RC parallel circuit in which a serial circuit including resistance R2 and Warburg resistance W0 is parallel connected to capacitor C2 corresponds to graph line (iii) in the Nyquist plot illustrated in FIG. 2A or FIG. 2B.

FIG. 4 is a perspective view illustrating one example of secondary battery 3. As illustrated in FIG. 4, secondary battery 3 is formed into a plate-like shape, and a plate-like electrode assembly including, for instance, a positive electrode plate, a negative electrode plate, a separator, and an electrolyte is housed in housing 23 of secondary battery 3.

Secondary battery 3 includes positive electrode side battery terminal 24a connected to the positive electrode plate and negative electrode side battery terminal 24b connected to the negative electrode plate, and has, for example, a structure in which positive electrode side battery terminal 24a and negative electrode side battery terminal 24b protrude from the same side of housing 23. Hereinafter, positive electrode side battery terminal 24a and negative electrode side battery terminal 24b are also referred to as battery terminals 24.

A laminated sheet is used as the material of the exterior body of housing 23. This laminated sheet comprises a metal foil (e.g., an aluminum foil) having resin sheets on the both sides thereof, and includes a thermoplastic and electrolyte-resistant resin such as polyethylene, polypropylene, and polyamide. By heat welding this thermoplastic resin, the edge portion of the exterior body is welded and the battery terminals are sealed by the exterior body.

When an electrode assembly in which battery terminals 24 are placed on the exterior body of housing 23 is sealed using a laminated sheet, it is preferable to sandwich the electrode assembly by the exterior body and seal the opening portion of the exterior body so that battery terminals 24 protrude from the exterior body.

A method of heat fusing a thermoplastic resin layer opposed on the innermost side by, for instance, heat sealing, impulse sealing, or high-frequency sealing is preferable as a sealing method, but the sealing method is not specifically limited to these sealing methods.

Next, the structure of the electrode assembly of secondary battery 3 will be described with reference to FIG. 5.

FIG. 5 is the configuration diagram of an electrode assembly according to Embodiment 1. FIG. 5 illustrates a cross section of the electrode assembly.

The electrode assembly of secondary battery 3 includes positive electrode plate 28, negative electrode plate 31, and separator 25 interposed between positive electrode plate 28 and negative electrode plate 31. Positive electrode plate 28 includes positive electrode current collector 27 and positive electrode active material layer 26 that contacts this positive electrode current collector 27. Positive electrode plate 31 includes negative electrode current collector 30 and negative electrode active material layer 29 that contacts this negative electrode current collector 30. Positive electrode active material layer 26 and negative electrode active material layer 29 are disposed to face separator 25 and are disposed opposed to each other with separator 25 interposed therebetween.

In the electrode assembly, positive electrode plate 28 and negative electrode plate 31 are alternately stacked. For example, in Embodiment 1, an electrode plate on one principal surface of the plate-like electrode assembly and an electrode plate on the other principal surface of the plate-like electrode assembly have the same polarity. For example, an electrode plate on one principal surface and an electrode plate on the other principal surface are positive electrode plates 28 having the same polarity, as illustrated in FIG. 5.

Positive electrode plate 28 on one principal surface of the electrode assembly or positive electrode plate 28 on the other principal surface of the electrode assembly each include positive electrode current collector 27 and positive electrode active material layer 26 that contacts one surface of this positive electrode current collector 27, and are referred to as positive electrode plates 28a. Positive electrode plate 28 interposed between positive electrode plate 28 on one principal surface and positive electrode plate 28 on the other principal surface includes positive electrode current collector 27 and two positive electrode active material layers 26 that contact both surfaces of this positive electrode current collector 27, and is referred to as positive electrode plate 28b.

When an electrode plate on one principal surface and an electrode plate on the other principal surface are positive electrode plates 28, negative electrode plate 31 interposed between positive electrode plate 28 on one principal surface and positive electrode plate 28 on the other principal surface includes negative electrode current collector 30 and two negative active material layers 29 that contact both surfaces of this negative electrode current collector 30.

Note that an electrode plate on one principal surface and an electrode plate on the other principal surface may be negative electrode plates 31, and in this case, negative electrode plate 31 on one principal surface side and negative electrode plate 31 on the other principal surface each include negative electrode current collector 30 and negative electrode active material layer 29 that contacts one surface of this negative electrode current collector 30.

Separator 25 has voids and insulates between a positive electrode and a negative electrode while transmitting an electrolyte and ions. In the case of using, for example, a lithium-ion secondary battery while the battery is being charged, electrons are supplied on the negative electrode side through an external circuit, and at the same time, lithium ions migrate from the positive electrode via the electrolyte and are accumulated in the negative electrode. While the battery is being discharged, the lithium ions accumulated in the negative electrode migrate from the positive electrode via the electrolyte and electrons are supplied to the external circuit. Note that separator 25 can be formed of a solid electrolyte.

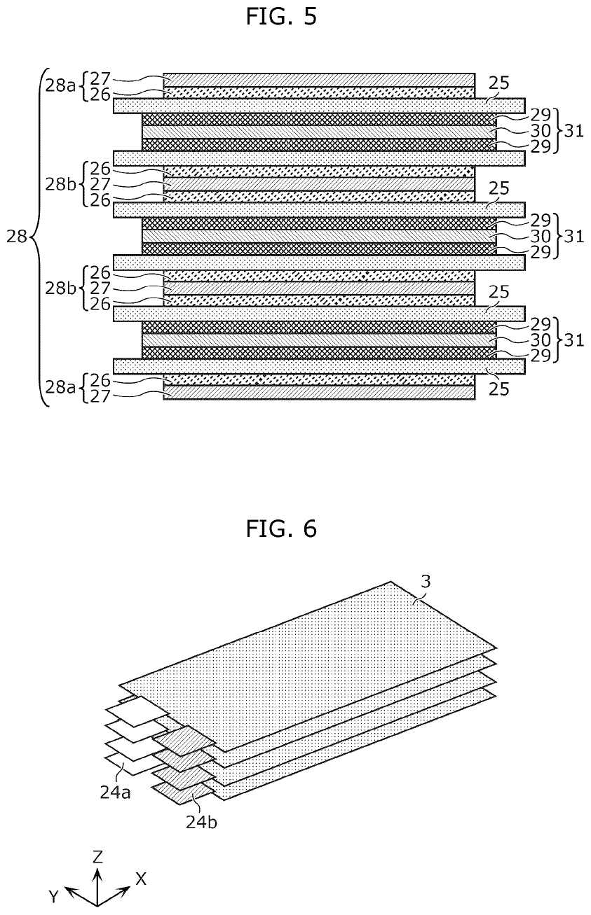

Next, an arrangement of a plurality of secondary batteries 3 included in assembled battery 4 will be described with reference to FIG. 6.

FIG. 6 is a perspective view illustrating the arrangement of the plurality of secondary batteries 3 according to Embodiment 1.

As described above, in Embodiment 1, each of the plurality of secondary batteries 3 includes an electrode assembly in which positive electrode plate 28 and negative electrode plate 31 are alternately stacked, and an electrode plate on one principal surface of the electrode assembly and an electrode plate on the other principal surface of the electrode assembly have the same polarity.

Positive electrode side battery terminal 24a and negative electrode side battery terminal 24b of each of the plurality of secondary batteries 3 protrude in the same direction. Specifically, positive electrode side battery terminal 24a and negative electrode side battery terminal 24b protrude from the same side of housing 23 of secondary battery 3.

Positive electrode side battery terminals 24a of the plurality of secondary batteries 3 at least partially overlap each other when viewed from the stacking direction (the Z direction) of the plurality of secondary batteries 3, and negative electrode side battery terminals 24b of the plurality of secondary batteries 3 at least partially overlap each other when viewed from the stacking direction of the plurality of secondary batteries 3. For example, positive electrode side battery terminals 24a of the plurality of secondary batteries 3 may overlap so that the external shapes of positive electrode side battery terminals 24a match when viewed from the stacking direction of the plurality of secondary batteries 3, or one positive electrode side battery terminal 24a may overlap other positive electrode side battery terminal 24a to cover the whole of the other positive electrode side battery terminal 24a, or a part of one positive electrode side battery terminal 24a may overlap a part of other positive electrode side battery terminal 24a. Likewise, negative electrode side battery terminals 24b of the plurality of secondary batteries 3 may overlap so that the external shapes of negative electrode side battery terminals 24b match when viewed from the stacking direction of the plurality of secondary batteries 3, or one negative electrode side battery terminal 24b may overlap other negative electrode side battery terminal 24b to cover the whole of the other negative electrode side battery terminal 24b, or a part of one negative electrode side battery terminal 24b may overlap a part of other negative electrode side battery terminal 24b.

A plurality of secondary batteries 3 are connected in series to achieve a target battery capacity and a target battery voltage, to constitute assembled battery 4. Note that assembled battery 4 may include a plurality of secondary batteries 3 connected in parallel.

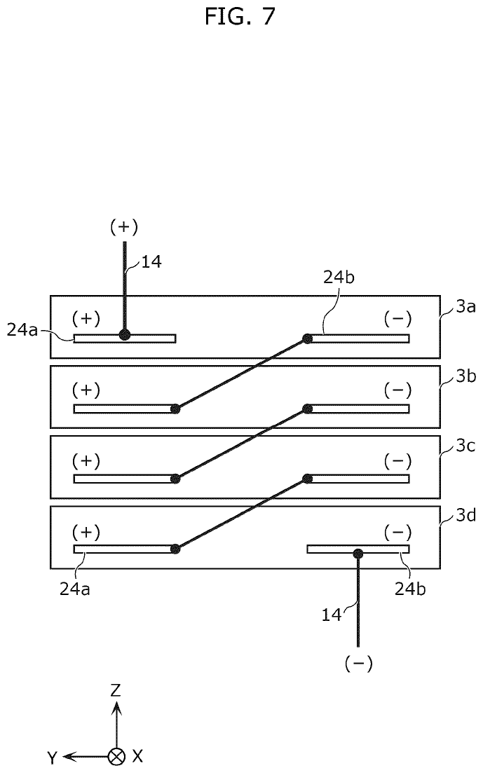

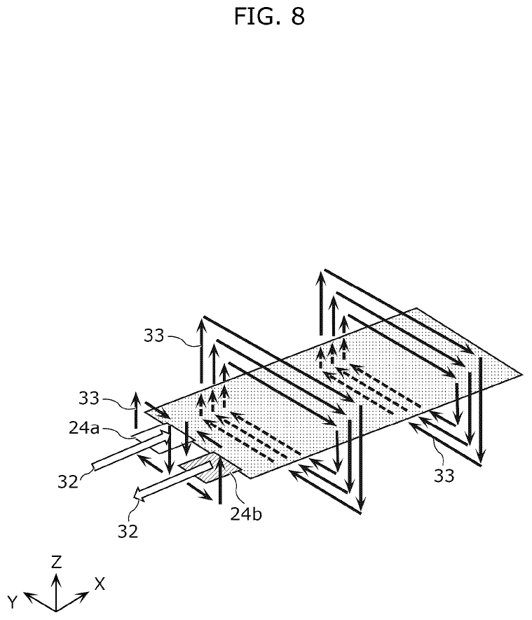

Next, the routing of current application line 14 that is connected to a plurality of secondary batteries 3 in assembled battery 4 will be described with reference to FIG. 7.

FIG. 7 is a diagram illustrating a method of connecting current application line 14 according to Embodiment 1.

FIG. 7 is a diagram when the plurality of secondary batteries 3 are viewed from a direction in which positive electrode side battery terminal 24a and negative electrode side battery terminal 24b protrude (the X direction). In FIG. 7, secondary batteries 3a to 3d are illustrated as the plurality of secondary batteries 3. The figure illustrates assembled battery 4 which includes the plurality of secondary batteries 3 connected in series in which positive electrode side battery terminals 24a and negative electrode side battery terminals 24b of the plurality of secondary batteries 3 are stacked in the Z direction. Positive electrode side battery terminal 24a of secondary battery 3a and negative electrode side battery terminal 24b of secondary battery 3d are connected to battery monitoring device 1 via current application line 14. Negative electrode side battery terminal 24b of secondary battery 3a is connected to positive electrode side battery terminal 24a of secondary battery 3b via current application line 14. Likewise, negative electrode side battery terminal 24b of secondary battery 3b is connected to positive electrode side battery terminal 24a of secondary battery 3c via current application line 14, and negative electrode side battery terminal 24b of secondary battery 3c is connected to positive electrode side battery terminal 24a of secondary battery 3d via current application line 14.

For example, current application line 14 is placed between positive electrode side battery terminal 24a and negative electrode side battery terminal 24b of each of the plurality of secondary batteries 3 in assembled battery 4, as illustrated in FIG. 7. With current application line 14 interposed between positive electrode side battery terminal 24a and negative electrode side battery terminal 24b of each of the plurality of secondary batteries 3, the length of current application line 14 can be made the shortest. It is therefore possible to suppress an influence caused by a magnetic flux generated from current application line 14, thereby suppressing an influence caused by electromagnetic induction disturbance.

For example, it is preferable that battery terminals 24 that protrude from secondary battery 3 are as short as possible and current application line 14 is placed in a position that is not distant from secondary battery 3. It is thus possible to suppress a magnetic flux generated when current flows through battery terminals 24 and also minimize the area of a current loop created by battery terminals 24 and secondary battery 3, thereby suppressing an influence caused by electromagnetic induction disturbance.

The detection of the voltage of secondary battery 3 can be performed by connecting battery monitoring device 1 to each of positive electrode side battery terminal 24a and negative electrode side battery terminal 24b via voltage detection line 17.

Next, the direction and occurrence location of a magnetic field generated from secondary battery 3 will be described with reference to FIG. 8 to FIG. 10.

FIG. 8 is a diagram for illustrating magnetic fluxes generated from secondary battery 3 according to Embodiment 1.

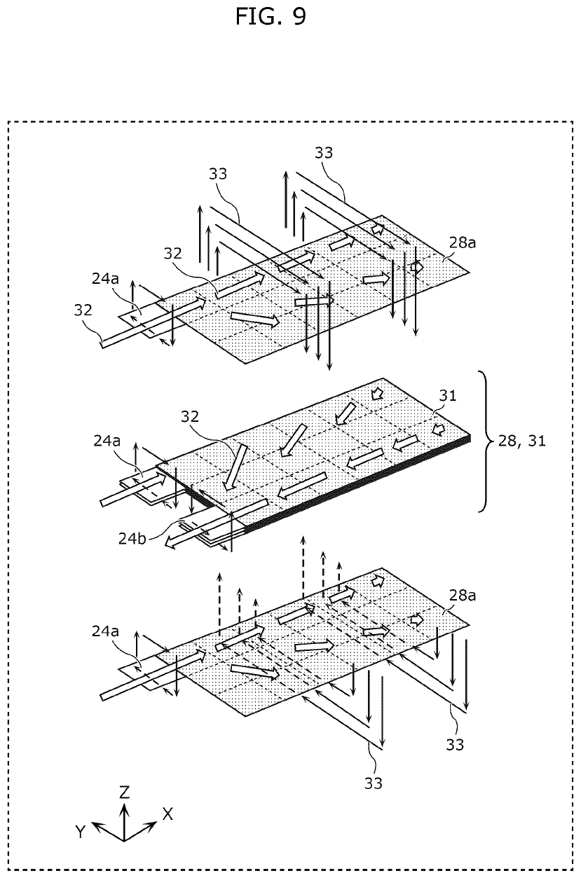

FIG. 9 is a diagram for illustrating magnetic fluxes generated from an electrode assembly according to Embodiment 1.

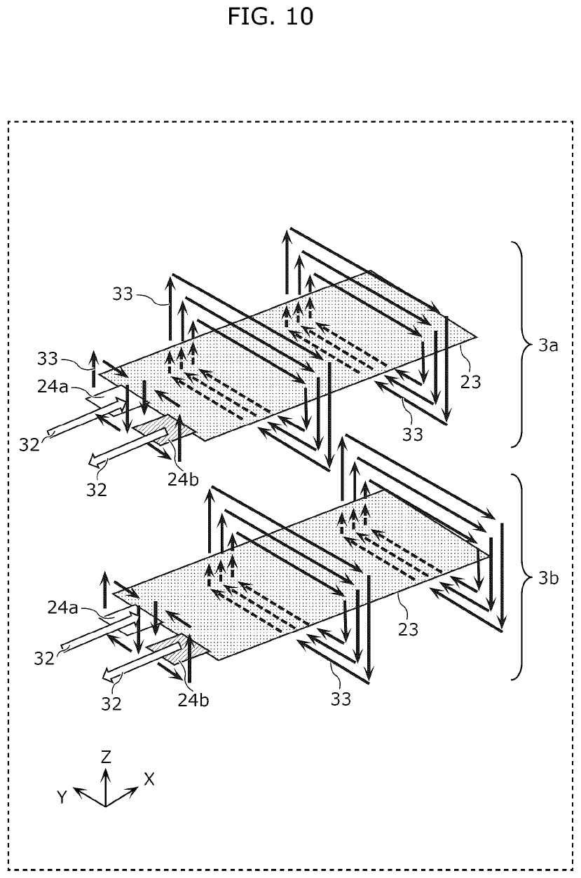

FIG. 10 is a diagram for illustrating interference of magnetic fluxes generated from neighboring secondary batteries 3 according to Embodiment 1.

FIG. 8 is a diagram illustrating a magnetic flux generated in secondary battery 3. When current flows through conductors, the current generates a magnetic field in a space. This magnetic field flows in a clockwise rotation direction vertical to the direction of current vector 32 illustrated in FIG. 8, in accordance with right-handed screw rules for amperes. Magnetic flux 33 illustrated in FIG. 8 indicates the direction of a magnetic field made by the current plane of secondary battery 3, and is characterized in that the magnetic flux on the current plane of secondary battery 3 is uniform regardless of the distance from the plane.

When current flows from positive electrode side battery terminal 24a in the direction of current vector 32, magnetic flux 33 is generated from housing 23 and battery terminals 24 of secondary battery 3 in a clockwise rotation direction with respect to current vector 32. Magnetic flux 33 is generated in a location where current flows through conductors, and to be more specific, magnetic flux 33 is generated in housing 23 including battery terminals 24 and electrodes. In a laminated secondary battery for which a laminated film is used for the material of housing 23, a magnetic flux generated in secondary battery 3 passes through the laminated film and gives an influence to the outside of secondary battery 3.

FIG. 9 is a diagram illustrating the directions and occurrence locations of magnetic fluxes 33 which take the structure of the electrode assembly of secondary battery 3 into consideration. The electrode assembly is a complex body in which positive electrode plate 28 and negative electrode plate 31 are alternately stacked in a plurality of layers. The degree of an influence in the vertical direction (the Z direction) of magnetic flux 33 from positive electrode plate 28a that is placed on the outermost surface of the electrode assembly is high among positive electrode plates 28 and negative electrode plates 31 that are stacked. The vertical direction is the stacking direction of the plurality of secondary batteries 3, as illustrated in FIG. 6. Accordingly, that the degree of an influence in the vertical direction of magnetic flux 33 from positive electrode plate 28a is high means that the degree of an influence of magnetic flux 33 from positive electrode plate 28a to other secondary battery 3 is high.

For example, positive electrode plate 28a on the positive Z-direction side illustrated in FIG. 9 is an electrode plate on one principal surface of the electrode assembly, and positive electrode plate 28a on the negative Z-direction side is an electrode plate on the other principal surface of the electrode assembly. As can be seen from FIG. 9, an electrode plate on one principal surface and an electrode plate on the other principal surface are positive electrode plates 28a and have the same polarity.

As illustrated in FIG. 9, the direction of current flowing through positive electrode plate 28 is an opposite direction of the direction of current flowing through negative electrode plate 31. Specifically, current vector 32 of the current flowing through positive electrode plate 28 is opposite to current vector 32 of the current flowing through negative electrode plate 31. As illustrated in the upper part and the lower part in FIG. 9, current flows through positive electrode current collector 27 of positive electrode plate 28a, which serves as a conductor, and magnetic flux 33 in the clockwise rotation direction with respect to current vector 32 is generated. In the portion sandwiched between positive electrode plate 28a on one principal surface of the electrode assembly and positive electrode pate 28a on the other principal surface of the electrode assembly, positive electrode plate 28 and negative electrode plate 31 whose current flowing directions are opposite are alternately stacked, and magnetic fluxes 33 generated in positive electrode plate 28 and negative electrode plate 31 in this portion overlap, and a magnetic flux combined in a lateral direction appears in secondary battery 3. The combined magnetic flux in the portion sandwiched between positive electrode plate 28a on one principal surface and positive electrode plate 28a on the other principal surface does not interfere with other secondary batteries 3 stacked in the vertical direction. Accordingly, as an influence caused by a magnetic flux generated from secondary battery 3 having an electrode assembly in which positive electrode plate 28 and negative electrode plate 31 are alternately stacked, an influence caused by a magnetic flux from an electrode plate on one principal surface (positive electrode plate 28a in this case) and a magnetic flux from an electrode plate on the other principal surface (positive electrode plate 28a in this case) is dominant.

FIG. 10 is a diagram for illustrating magnetic fluxes 33 that are present between two secondary batteries 3a and 3b among the plurality of secondary batteries 3 that are stacked, focusing on secondary batteries 3a and 3b. The two secondary batteries 3a and 3b are each provided with positive electrode plate 28a on the outermost surface of the electrode assembly, and magnetic flux 33 in the clockwise rotation direction with respect to current vector 32 from positive electrode side battery terminal 24a is generated.

In assembled battery 4 including the plurality of secondary batteries 3, magnetic fluxes 33 generated by current affect each other. Magnetic fluxes 33 become stronger in a location where the directions of magnetic fluxes 33 are same and are offset in a location where the directions of magnetic fluxes 33 are opposite and thus become weaker. The direction of a magnetic flux generated in secondary battery 3a and the direction of a magnetic flux generated in secondary battery 3b are opposite and the magnetic fluxes are thus offset.

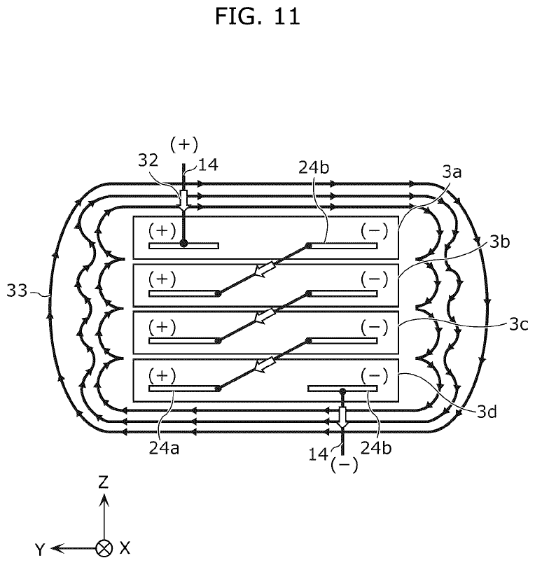

FIG. 11 is a diagram for illustrating magnetic fluxes 33 generated from assembled battery 4 according to Embodiment 1. FIG. 11 is a diagram illustrating assembled battery 4 including a plurality of secondary batteries 3 (secondary batteries 3a to 3d in this case) connected in series when assembled battery 4 is viewed from the battery terminal 24 side (the negative X direction side).

As illustrated in FIG. 11, positive electrode side battery terminals 24a of secondary batteries 3a to 3d are stacked so as to overlap each other when viewed from the Z direction, and negative electrode side battery terminals 24b are stacked so as to overlap each other when viewed from the Z direction. Current flows from positive electrode side battery terminal 24a of secondary battery 3a, and magnetic flux 33 with respect to current vector 32 illustrated in FIG. 10 is generated in each of secondary batteries 3a to 3d.

As illustrated in FIG. 11, since secondary batteries 3 are stacked in the same direction, magnetic fluxes 33 generated in the outer peripheries of secondary batteries 3 are combined in the same direction, while magnetic fluxes between secondary batteries 3 are offset. With this, magnetic fluxes 33 between secondary batteries 3 included in assembled battery 4 do not interfere with other secondary batteries 3, and it is thus possible to accurately measure the internal AC impedance of each secondary battery 3.

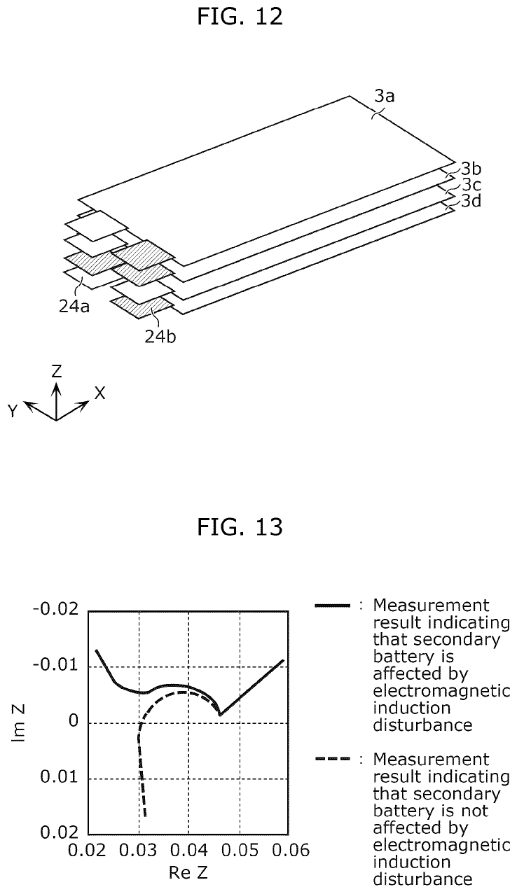

Next, an arrangement of a plurality of secondary batteries 3 included in assembled battery 4 when the plurality of secondary batteries 3 are affected by magnetic fields will be described with reference to FIG. 12.

FIG. 12 is a perspective view illustrating the arrangement of secondary batteries 3 that causes electromagnetic induction disturbance.

As illustrated in FIG. 12, secondary batteries 3a to 3d are stacked in the same direction, as is the case illustrated in FIG. 6, but only secondary battery 3c is placed with its front and rear in reverse. In this arrangement, when AC current is applied to secondary batteries 3a to 3d, an influence caused by a magnetic field generated in secondary battery 3c placed with its front and rear in reverse appears greatly as illustrated in FIG. 13, when compared with an influence caused by a magnetic field generated in secondary battery 3a, 3b, or 3d.

FIG. 13 is a diagram illustrating an influence caused by electromagnetic induction disturbance.

In the arrangement illustrated in FIG. 12, an influence in the high-frequency range in the Nyquist plot appears greatly, as illustrated in FIG. 13. Thus, a phenomenon in which the surrounding batteries or circuits are affected by a magnetic field is referred to as electromagnetic induction disturbance. The size of the magnetic field increases as current of the occurrence source of the magnetic field increases.

With battery pack 2 according to Embodiment 1, positive electrode plate 28a on the outermost surface of each of the plurality of secondary batteries 3 and positive electrode plate 28a on the outermost surface of a secondary battery adjacent in the stacking direction of the plurality of secondary batteries 3 have the same polarity, and it is thus possible to mutually weaken magnetic fluxes generated from positive electrode plates 28a on the outermost surfaces that have the same polarity in neighboring secondary batteries 3. Accordingly, magnetic fluxes generated in secondary batteries 3 included in assembled battery 4 are less likely to interfere with other secondary batteries 3, and it is thus possible to accurately measure the internal AC impedance of each secondary battery 3.

It is also possible, between neighboring secondary batteries 3, to mutually weaken magnetic fluxes generated from positive electrode battery terminals 24a of the neighboring secondary batteries 3, and to mutually weaken magnetic fluxes generated from negative electrode side battery terminals 24b of the neighboring secondary batteries 3. Accordingly, magnetic fluxes generated in secondary batteries 3 included in assembled battery 4 are much less likely to interfere with other secondary batteries 3, and it is thus possible to more accurately measure the internal AC impedance of each secondary battery 3.

With such battery pack 2, even when assembled battery 4 includes laminated secondary batteries, magnetic fluxes generated in a laminated secondary battery included in assembled battery 4 are less likely to interfere with other laminated secondary batteries, and it is thus possible to accurately measure the internal AC impedance of each laminated secondary battery. By using laminated secondary batteries for battery pack 2, it is easier to process battery pack 2 and make battery pack 2 thinner.

### Embodiment 2

Secondary battery 3 according to Embodiment 2 will be described.

Although Embodiment 1 illustrates an example in which an electrode plate on one principal surface of the electrode assembly and an electrode plate on the other principal surface of the electrode assembly have the same polarity, in Embodiment 2, positive electrode plate 28 is placed on one principal surface of the electrode assembly and negative electrode plate 31 is placed on the other principal surface of the electrode assembly. Since other points are basically the same as Embodiment 1, the following mainly focuses on differences.

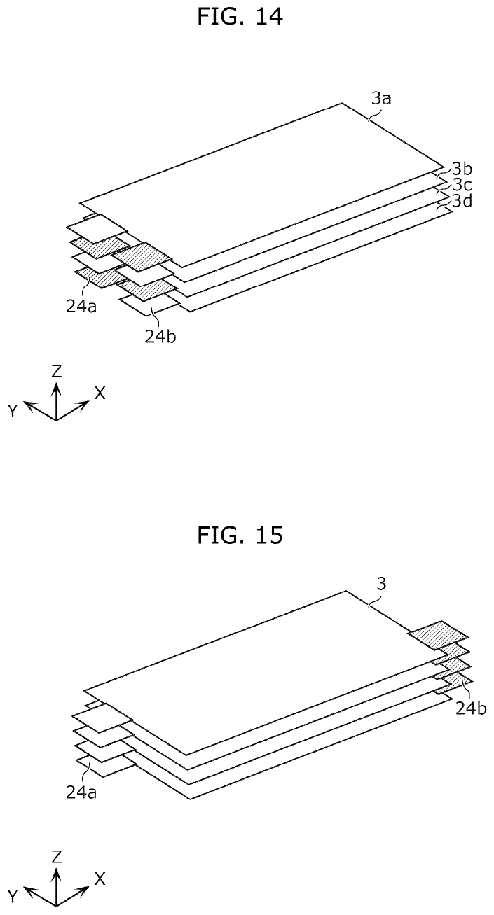

FIG. 14 is a perspective view illustrating an arrangement of a plurality of secondary batteries 3 (secondary batteries 3a to 3d in this case) according to Embodiment 2.

As described above, in Embodiment 2, positive electrode plate 28 and negative electrode plate 31 are placed on the outermost surfaces of the electrode assembly.

In the structure of the electrode assembly of secondary battery 3, when the outermost surfaces of the electrode assembly are each positive electrode plate 28a including positive electrode current collector 27 and positive electrode active material layer 26 that contacts one surface of this positive electrode current collector 27, the magnetic field of secondary battery 3 is generated in a clockwise rotation direction with respect to the direction of current. When the outermost surfaces of the electrode assembly are each negative electrode plate 31 including negative electrode current collector 30 and negative electrode active material layer 29 that contacts one surface of this negative electrode current collector 30, the direction of current is opposite and the direction of the magnetic field is also opposite. When the outermost surfaces are both negative electrode plates 31, secondary batteries 3 are stacked so that the front and rear of secondary battery 3 is same among secondary batteries 3, as is the case described in Embodiment 1. However, when the outermost surfaces of the electrode assembly are positive electrode plate 28 and negative electrode plate 31, each of the plurality of secondary batteries 3 is stacked so that positive electrode plate 28 on one principal surface of each of secondary batteries 3 is adjacent to positive electrode plate 28 on one principal surface of neighboring secondary battery 3, and negative electrode plate 31 on one principal surface of each of secondary batteries 3 is adjacent to negative electrode plate 31 on the other principal surface of neighboring secondary battery 3.

Specifically, focusing on secondary battery 3c, positive electrode plate 28 on one principal surface of secondary battery 3c is adjacent to positive electrode plate 28 on one principal surface of secondary battery 3b adjacent to secondary battery 3c on the positive electrode plate 28 side (e.g., the positive Z direction side) on one principal surface of secondary battery 3c, and negative electrode plate 31 on the other principal surface of secondary battery 3c is adjacent to negative electrode plate 31 on the other principal surface of secondary battery 3d adjacent to secondary battery 3c on the negative electrode plate 31 side (e.g., the negative Z direction side) on the other principal surface of secondary battery 3c.

In this case: positive electrode side battery terminal 24a and negative electrode side battery terminal 24b of each of the plurality of secondary batteries 3 protrude in the same direction; positive electrode side battery terminal 24a of each of the plurality of secondary batteries 3 overlaps at least partially with negative electrode side battery terminal 24b of secondary battery 3 adjacent in the stacking direction (the Z direction) of the plurality of secondary batteries 3 when the plurality of secondary batteries 3 are viewed from the stacking direction; and negative electrode side battery terminal 24b of each of the plurality of secondary batteries 3 overlaps at least partially with positive electrode side battery terminal 24a of secondary battery 3 adjacent in the stacking direction when the plurality of secondary batteries 3 are viewed from the stacking direction, as illustrated in FIG. 14. For example, when viewed from the stacking direction of the plurality of secondary batteries 3, positive electrode side battery terminal 24a may overlap negative electrode side battery terminal 24b so that the external shape of positive electrode side battery terminal 24a matches the external shape of negative electrode side battery terminal 24b, or positive electrode side battery terminal 24a may overlap negative electrode side battery terminal 24b to cover the entire negative electrode side battery terminal 24b, or a part of positive electrode side battery terminal 24a may overlap a part of negative electrode side battery terminal 24b. For example, when viewed from the stacking direction of the plurality of secondary batteries 3, negative electrode side battery terminal 24b may overlap positive electrode side battery terminal 24a so that the external shape of negative electrode side battery terminal 24b matches the external shape of positive electrode side battery terminal 24a, or negative electrode side battery terminal 24b may overlap positive electrode side battery terminal 24a to cover the entire positive electrode side battery terminal 24a, or a part of positive electrode side battery terminal 24a may overlap a part of negative electrode side battery terminal 24b.

Thus, since the direction of a magnetic field changes depending on a battery structure, it is necessary to employ a method of arranging secondary batteries 3 that aims to offset magnetic fields. When positive electrode plate 28 is placed on one principal surface of the electrode assembly and negative electrode plate 31 is placed on the other principal surface of the electrode assembly, for example, with each of the plurality of secondary batteries 3 being stacked so that positive electrode side battery terminal 24a and negative electrode side battery terminal 24b of each of the plurality of secondary batteries 3 overlap, it is possible to cause electrode plates on the outermost surfaces of neighboring secondary batteries 3 adjacent in the stacking direction of the plurality of secondary batteries 3. With this, an electrode plate on the outermost surface of each of the plurality of secondary batteries 3 has the same polarity as an electrode plate on the outermost surface of a secondary battery adjacent in the stacking direction, and it is thus possible, between neighboring secondary batteries 3, to mutually weaken magnetic fluxes generated from the electrode plates, of the neighboring secondary batteries 3, that have the same polarity. Accordingly, magnetic fluxes generated in secondary batteries 3 included in assembled battery 4 are less likely to interfere with other secondary batteries 3, and it is thus possible to accurately measure the internal AC impedance of each secondary battery 3.

### Embodiment 3

Secondary battery 3 according to Embodiment 3 will be described.

Embodiment 1 illustrates an example in which positive electrode side battery terminal 24a and negative electrode side battery terminal 24b of each of the plurality of secondary batteries 3 protrude in the same direction. In Embodiment 3, however, positive electrode side battery terminal 24a and negative electrode side battery terminal 24b of each of a plurality of secondary batteries 3 protrude in opposite directions. Since other points are basically the same as Embodiment 1, the following mainly focuses on differences.

FIG. 15 is a perspective view illustrating an arrangement of a plurality of secondary batteries 3 according to Embodiment 3.

As illustrated in FIG. 15, secondary battery 3 has a structure in which positive electrode side battery terminal 24a and negative electrode side battery terminal 24b protrude from different sides of housing 23. In Embodiment 3, positive electrode plate 28a is placed on the outermost surface of the electrode assembly and a magnetic flux in a clockwise rotation direction with respect to the direction of current flowing from positive electrode side battery terminal 24a is generated, as is the case described in Embodiment 1.

Even when secondary battery 3 has a structure in which battery terminals 24 protrude from different sides of secondary battery 3, if positive electrode plates (e.g., positive electrode plates 28a) having the same polarity are placed on the outermost surfaces of the electrode assembly, magnetic flux 33 in the clockwise rotation direction with respect to the direction of current flowing from positive electrode side battery terminal 24a is generated. For this reason, with a plurality of secondary batteries 3 being stacked so that positive electrode side battery terminals 24a of secondary batteries 3 at least partially overlap each other when viewed from the stacking direction of secondary batteries 3 and negative electrode side battery terminals 24b of secondary batteries 3 at least partially overlap each other when secondary batteries 3 are viewed from the stacking direction, it is possible to accurately measure the internal AC impedance of each secondary battery 3.

Moreover, since the direction of current is different between positive electrode side battery terminal 24a and negative electrode side battery terminal 24b, when the distance between positive electrode side battery terminal 24a and negative electrode side battery terminal 24b is large, as illustrated in FIG. 15, there is no interference of magnetic fluxes 33 between battery terminals 24, and it is thus possible to more accurately measure the internal AC impedance of each secondary battery 3.

### Embodiment 4

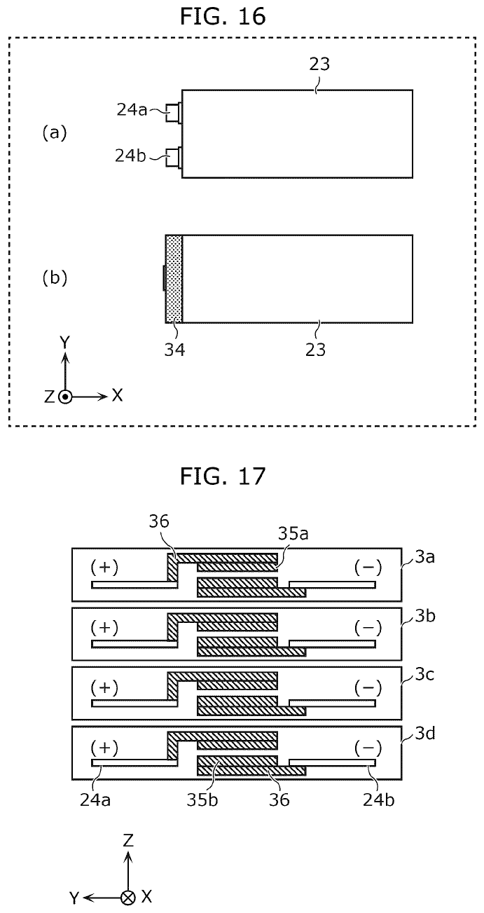

Next, a method of connecting a plurality of secondary batteries 3 using connectors 34 according to Embodiment 4 will be described with reference to FIG. 16 to FIG. 19.

FIG. 16 is a plan view illustrating one example of secondary battery 3 and connector 34 according to Embodiment 4.

FIG. 17 is a diagram illustrating wires 36 that connect battery terminals 24 and connectors 34 according to Embodiment 4.

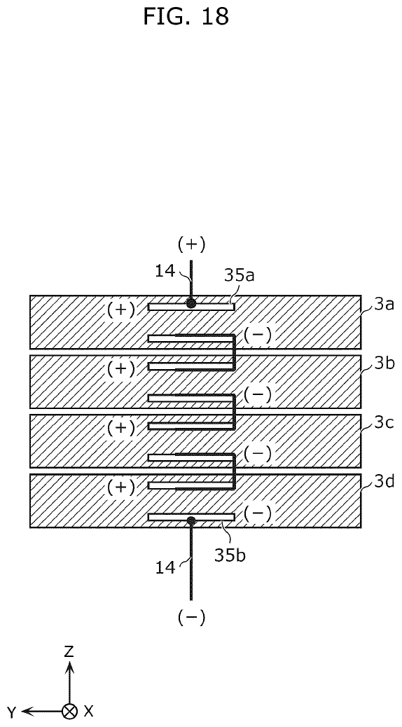

FIG. 18 is a diagram illustrating a method of connecting current application line 14 according to Embodiment 4.

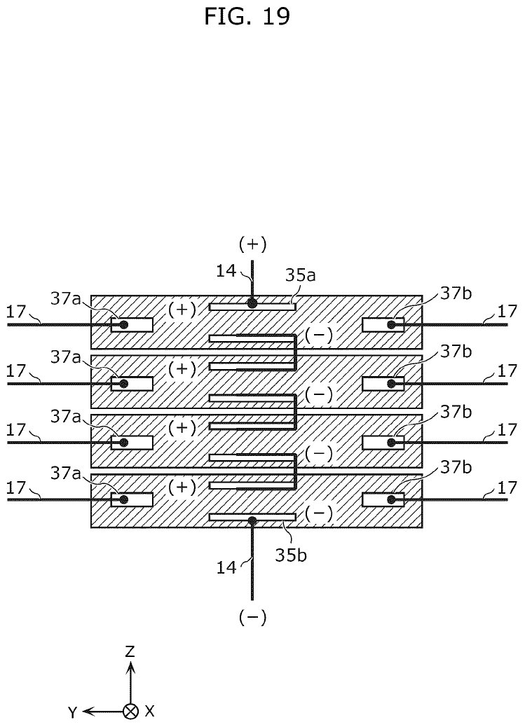

FIG. 19 is a diagram illustrating a method of connecting voltage detection lines 17 according to Embodiment 4.

(a) in FIG. 16 illustrates secondary battery 3 before connector 34 is attached thereto, and (b) in FIG. 16 illustrates secondary battery 3 with connector 34 attached thereto. As illustrated in FIG. 17, connector 34 changes the arrangement of positive electrode side battery terminal 24a and negative electrode side battery terminal 24b aligned in the lateral direction (the Y direction) to the arrangement in the up-down direction (the Z direction). FIG. 17 illustrates wires 36 each of which connects connector 34 to positive electrode side battery terminal 24a and negative electrode side battery terminal 24b.

Connector 34 is provided with positive electrode side battery terminal 35a and negative electrode side battery terminal 35b that connect positive electrode side battery terminal 24a and negative electrode side battery terminal 24b to connector 34, and current can be input to or output from positive electrode side battery terminal 35a and negative electrode side battery terminal 35b of connector 34 to positive electrode side battery terminal 24a and negative electrode side battery terminal 24b via wires 36. Note that an insulator is provided on the surface of wire 36 so that wires 36 do not come into contact with each other and are short-circuited.

FIG. 18 illustrates one example of secondary battery 3 when positive electrode side battery terminal 24a (positive electrode side battery terminal 35a to be specific) and negative electrode side battery terminal 24b (negative electrode side battery terminal 35b to be specific) are arranged in the up-down direction by connector 34 and these battery terminals are connected by current application line 14.

FIG. 18 illustrates secondary batteries 3 (secondary batteries 3a to 3d in this case) connected in series by connectors 34. In Embodiment 4, current application line 14 is connected to positive electrode side battery terminal 35a on the connector 34 side and negative electrode side battery terminal 35b on the connector 34 side, and is not connected to positive electrode side battery terminal 24a and negative electrode side battery terminal 24b.

Positive electrode side battery terminal 35a of secondary battery 3a on the connector 34 side and negative electrode side battery terminal 35b of secondary battery 3d on the connector 34 side are connected to battery monitoring device 1 by current application line 14. Negative electrode side battery terminal 35b of secondary battery 3a on the connector 34 side and positive electrode side battery terminal 35a of secondary battery 3b on the connector 34 side are connected via current application line 14. Likewise, negative electrode side battery terminal 35b of secondary battery 3b on the connector 34 side and positive electrode side battery terminal 35a of secondary battery 3c on the connector 34 side are connected via current application line 14, and negative electrode side battery terminal 35b of secondary battery 3c on the connector 34 side and positive electrode side battery terminal 35a of secondary battery 3d on the connector 34 side are connected via current application line 14.

Current application line 14 may be connected to positive electrode side battery terminal 35a on the connector 34 side and negative electrode side battery terminal 35b on the connector 34 side by, for instance, a wire formed into an L shape or a U shape, or a bus bar.

FIG. 19 is a diagram illustrating one example of the arrangement of voltage detection lines 17 of connectors 34 according to Embodiment 4. FIG. 19 also illustrates the arrangement of current application line 14. Positive electrode side voltage terminal 37a on the connector 34 side and negative electrode side voltage terminal 37b on the connector 34 side that are connected to positive electrode side battery terminal 24a and negative electrode side battery terminal 24b are provided for connector 34, and positive electrode side voltage terminal 37a on the connector 34 side and negative electrode side voltage terminal 37b on the connector 34 side are respectively connected to voltage detection lines 17.

Thus, in Embodiment 4, battery pack 2 further includes connectors 34 that place battery terminals 24 included in the plurality of secondary batteries 3 to overlap each other when the plurality of secondary batteries 3 are viewed from the stacking direction. By routing current application line 14 and voltage detection lines 17 using connectors 34, it is possible to minimize the area of a current loop, thereby suppressing an influence caused by electromagnetic induction disturbance. Thus, it is possible to more accurately measure the internal AC impedances of the plurality of secondary batteries 3 included in assembled battery 4.

Connector 34 according to Embodiment 4 can be applied to battery pack 2 according to any one of Embodiments 1 through 3.

### Embodiment 5

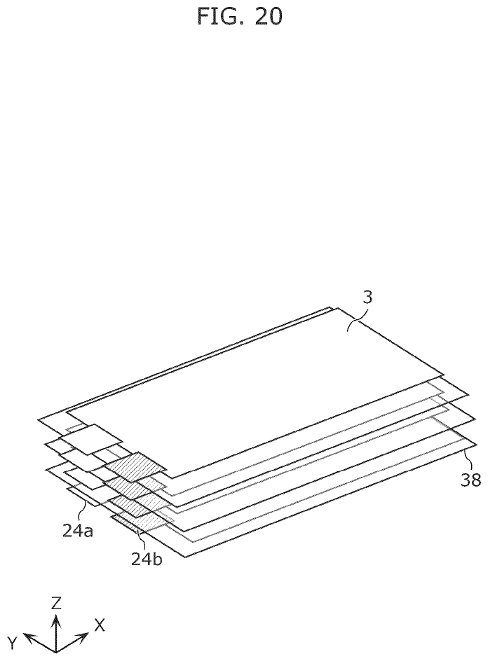

Next, assembled battery 4 provided with electromagnetic shields 38 according to Embodiment 5 will be described with reference to FIG. 20.

FIG. 20 is a perspective view illustrating an arrangement example of electromagnetic shields 38 according to Embodiment 5. Electromagnetic shield 38 is one example of a shielding part that shields electric fields or magnetic fields generated by a plurality of secondary batteries 3. Electromagnetic shields 38 may be disposed to cover housings 23 or battery terminals 24 of the plurality of secondary batteries 3, to shield electric fields or magnetic fields generated by housings 23 or battery terminals 24 of the plurality of secondary batteries 3. Electromagnetic shield 38 includes, for example, a metal tape including, for instance, copper or aluminum, or mesh-like wires. With this, electromagnetic shield 38 can have a shielding function against electric fields or magnetic fields.

Thus, it is possible, by electromagnetic shield 38, to suppress an influence caused by an electric field or a magnetic field generated by secondary battery 3 (housing 23 portion or battery terminals 24). Note that connector 34 may have a shielding function against an electric field or a magnetic field, in which case, it is possible to suppress an influence caused by an electric field or a magnetic field generated from battery terminals 24.

With this, it is possible to more accurately measure the internal AC impedances of the plurality of secondary batteries 3 included in assembled battery 4.

Electromagnetic shield 38 according to Embodiment 5 can be applied to battery pack 2 according to any one of Embodiments 1 through 3, and connector 34 can be applied to battery pack 2 according to any one of Embodiments 1 through 3 to which connector 34 is applied.

(Other Embodiments)

Although battery pack 2 according to a plurality of aspects of the present disclosure has been described above based on the embodiments, the present disclosure is not limited to these embodiments. Other embodiments obtained by various modifications to any of the embodiments and the variations which may be conceived by those skilled in the art may be also included in the scope of the plurality of aspects of the present disclosure so long as they do not depart from the essence of the present disclosure.

Although each of the above embodiments has illustrated a laminated battery as an example of secondary battery 3, secondary battery 3 may be a battery having a different shape, such as a cylindrical shape or a flat plate shape, so long as secondary battery 3 is a battery greatly affected by a magnetic field when high-frequency AC current is applied to the battery and an influence caused by the magnetic field appears greatly in the high-frequency range in a Nyquist plot.

Although each of the above embodiments illustrates an example in which a battery pack is applied to a vehicle power supply system, the battery pack is also effective for storage batteries, motor bicycles, heavy equipment, ships, airplanes, and power plants. Moreover, although an example in which lithium-ion secondary batteries are used as secondary batteries 3 is illustrated in each of the above embodiments, secondary batteries 3 may be other secondary batteries (lead-acid batteries, nickel-cadmium storage batteries, metal-lithium batteries, lithium-ion polymer secondary batteries, sodium-ion batteries, solid-state batteries, etc.).

Although each of the above embodiments illustrates secondary battery 3 as an example of a power storage device, the power storage device may be a lithium-ion capacitor.

### Industrial Applicability

The present disclosure is applicable as a battery pack having a function of monitoring the states of secondary batteries such as lithium-ion secondary batteries.

1. A battery pack comprising:
an assembled battery in which a plurality of power storage devices are connected;
a current application line for applying current to the assembled battery;
voltage detection lines for detecting voltages of the plurality of power storage devices; and
a battery monitoring device that measures internal impedances of the plurality of power storage devices via the current application line and the voltage detection lines, wherein
each of the plurality of power storage devices includes an electrode assembly in which a positive electrode plate and a negative electrode plate are alternately stacked, and an electrode plate on one principal surface of the electrode assembly and an electrode plate on an other principal surface of the electrode assembly have a same polarity,
a direction of current that flows through the positive electrode plate is an opposite direction of a direction of current that flows through the negative electrode plate, and
each of the plurality of power storage devices is stacked.

2. The battery pack according to claim 1, wherein
a positive electrode side battery terminal and a negative electrode side battery terminal of each of the plurality of power storage devices protrude in a same direction,
the positive electrode side battery terminals of the plurality of power storage devices at least partially overlap each other when viewed from a stacking direction of the plurality of power storage devices, and
the negative electrode side battery terminals of the plurality of power storage devices at least partially overlap each other when viewed from the stacking direction of the plurality of power storage devices.

3. The battery pack according to claim 1, wherein
a positive electrode side battery terminal and a negative electrode side battery terminal of each of the plurality of power storage devices protrude in opposite directions,
the positive electrode side battery terminals of the plurality of power storage devices at least partially overlap each other when viewed from a stacking direction of the plurality of power storage devices, and
the negative electrode side battery terminals of the plurality of power storage devices at least partially overlap each other when viewed from the stacking direction of the plurality of power storage devices.

4. A battery pack comprising:
an assembled battery in which a plurality of power storage devices are connected;
a current application line for applying current to the assembled battery;
voltage detection lines for detecting voltages of the plurality of power storage devices; and
a battery monitoring device that measures internal impedances of the plurality of power storage devices via the current application line and the voltage detection lines, wherein
each of the plurality of power storage devices includes an electrode assembly in which a positive electrode plate and a negative electrode plate are alternately stacked, the positive electrode plate is placed on one principal surface of the electrode assembly, and the negative electrode plate is placed on an other principal surface of the electrode assembly,
a direction of current that flows through the positive electrode plate is an opposite direction of a direction of current that flows through the negative electrode plate, and
each of the plurality of power storage devices is stacked so that the positive electrode plate on the one principal surface of the electrode assembly in each of the plurality of power storage devices is adjacent to the positive electrode plate on the one principal surface of the electrode assembly in a neighboring power storage device, and the negative electrode plate on the other principal surface of the electrode assembly in each of the plurality of power storage devices is adjacent to the negative electrode plate on the other principal surface of the electrode assembly in a neighboring power storage device.

5. The battery pack according to claim 4, wherein
a positive electrode side battery terminal and a negative electrode side battery terminal of each of the plurality of power storage devices protrude in a same direction,
the positive electrode side battery terminals of the plurality of power storage devices at least partially overlap each other when viewed from a stacking direction of the plurality of power storage devices, and
the negative electrode side battery terminals of the plurality of power storage devices at least partially overlap each other when viewed from the stacking direction of the plurality of power storage devices.

6. The battery pack according to claim 1, wherein
each of the plurality of power storage devices has a structure in which the electrode assembly is sealed by a laminated sheet including a resin layer and a metal layer.

7. The battery pack according to claim 1, wherein
in the assembled battery, the current application line is placed between a positive electrode side battery terminal and a negative electrode side battery terminal of each of the plurality of power storage devices.

8. The battery pack according to claim 1, further comprising:
a connector that places battery terminals included in the plurality of power storage devices so as to overlap each other when viewed from a stacking direction of the plurality of power storage devices.

9. The battery pack according to claim 1, further comprising:
a shielding part that shields an electric field or a magnetic field generated by the plurality of power storage devices.
